(19) United States
(12) Patent Application Publication
(10) Pub. No.: US 2009/0140373 A1
(43) Pub. Date: Jun. 4, 2009

(54) Method of Manufacturing LCD Driver IC

(76) Inventor: Chung Kyung JUNG, Anyang-si (KR)

Correspondence Address: THE LAW OFFICES OF ANDREW D. FORTNEY, PH.D., P.C., 401 W FALLBROOK AVE STE 204, FRESNO, CA, 93711-5835, US

(21) Appl. No.: 12/325,112

(22) Filed: Nov. 28, 2008

(30) Foreign Application Priority Data
Nov. 30, 2007 (KR) 10-2007-0123431

(51) Int. Cl. H01L 21/28; H01L 27/088

(52) U.S. Cl. 257/500; 438/595; 257/E21.19; 257/E27.06

(57) ABSTRACT

Disclosed is a method of manufacturing an LCD driver IC. The method includes forming a plurality of gate patterns on a semiconductor substrate by sequentially forming a plurality of gate insulating films and gate electrodes; sequentially depositing a plurality of spacer material layers covering the gate electrodes; forming spacers on the side walls of the gate electrodes by performing an etchback process on the plurality of spacer material layers such that the lowermost spacer material layer remains on the semiconductor substrate; and controlling the thickness of the lowermost spacer material layer (or removing the lowermost spacer material layer) by etching the lowermost spacer material layer.

This application claims the benefit of Korean Patent Application No. 10-2007-0123431, filed on Nov. 30, 2007 which is hereby incorporated by reference as if fully set forth herein.

### BACKGROUND OF THE INVENTION

1. Field of the Invention

The present invention relates to a semiconductor device and a method of manufacturing a semiconductor device, and more particularly, to an LCD driver IC and a method of manufacturing an LCD driver IC.

2. Discussion of the Related Art

Liquid crystal display devices are capable of serving as low-power, high-definition, and large-scale display devices, and are thus being vigorously researched now. A liquid crystal display device includes a liquid crystal panel, and an LCD driver IC (sometimes referred to as an LDI) to drive the liquid crystal panel. The liquid crystal panel includes a plurality of pixel units, each of which includes a liquid crystal capacitor and a thin film transistor to switch the liquid crystal capacitor on and off. The pixel units are connected to source and gate lines of the liquid crystal panel and are arranged in a matrix, and the source and gate lines are connected to the LCD driver IC.

The driver IC includes a source driver driving the source lines and a gate driver driving the gate lines. Recently, a driver IC that includes only a source driver (the gate driver being installed in the liquid crystal panel) has been proposed. In general, an LCD driver IC includes transistors operating in various driving voltage regions to display different gray scales and colors on a liquid crystal panel. These transistors of the driver IC are generally on one semiconductor substrate, integrated into a single chip.

Among processes for forming the above transistors, a spacer formation process may not be precisely controlled by the various restriction factors during the manufacturing process. For example, when an etchback process for forming spacers is excessively performed, exposed active regions of the semiconductor substrate may be over-etched, and when the etchback process is insufficiently performed, undesired spacer material may remain on the active regions.

FIG. 1 is a cross-sectional view conceptually illustrating the effects of the spacer formation process on the performance of transistors 1, 2, and 3 of a driver IC. Here, reference numeral 10 represents a semiconductor substrate, reference numeral 15 represents an isolation layer, reference numeral 21 represents a gate insulating layer, reference numeral 22 represents gate electrodes, reference numeral 23 represents spacers, and reference numeral 20 represents gates.

In the transistors 1, 2, and 3 disposed in pixel control regions of the driver IC, in the case where the etchback process for forming spacers is not sufficiently performed and thus a spacer material layer 23a remains on the active regions, the remaining spacer material layer 23a may serve as a barrier layer to impurity ions in a subsequent ion implantation process, and thereby impurities may not be precisely implanted to a designated depth. More particularly, in the high-voltage transistors 3, when impurities are not implanted to the designated depth and are relatively shallow in the vicinity of the source/drain regions, a junction current (e.g., leakage current) may be generated, and thus cause relatively poor performance and/or malfunction of the IC. Further, in the case where the etchback process is excessively performed (e.g., to solve the above problem), the high-voltage transistors 3 may not have any problem, but the reliability of the low-voltage transistors 1 and the middle-voltage transistors 2 may decrease due to damaged active regions (e.g., from overetching or from ion implantation directly into the substrate). Also, in transistors disposed in logic regions of the driver IC, in the same manner as the above-described transistors in the pixel control regions, when the spacer material layer(s) on the active regions are excessively etched, problems such as the decrease in reliability of the IC during driving, may be caused.

### SUMMARY OF THE INVENTION

Accordingly, the present invention is directed to an LCD driver IC and a method of manufacturing an LCD driver IC.

One object of the present invention is to provide an LCD driver IC and a method of manufacturing an LCD driver IC with transistors having various operating voltages, in which the thickness of a spacer material layer to form spacers is precisely controlled such that an ion implantation process is performed as it is designed.

To achieve this object and other advantages in accordance with the purpose of the invention, as embodied and broadly described herein, a method of manufacturing an LCD driver IC may include forming a plurality of gate patterns on a semiconductor substrate by sequentially forming gate insulating films and gate electrodes thereon; sequentially depositing a plurality of spacer material layers covering the gate electrodes; forming spacers respectively on the side walls of the gate electrodes by performing an etchback process on the plurality of spacer material layers such that the lowermost spacer material layer remains on the semiconductor substrate; and controlling the thickness of (or removing) the lowermost spacer material layer by etching the lowermost spacer material layer.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a cross-sectional view conceptually illustrating the effects of a spacer formation process on the performance of transistors in a driver IC; and

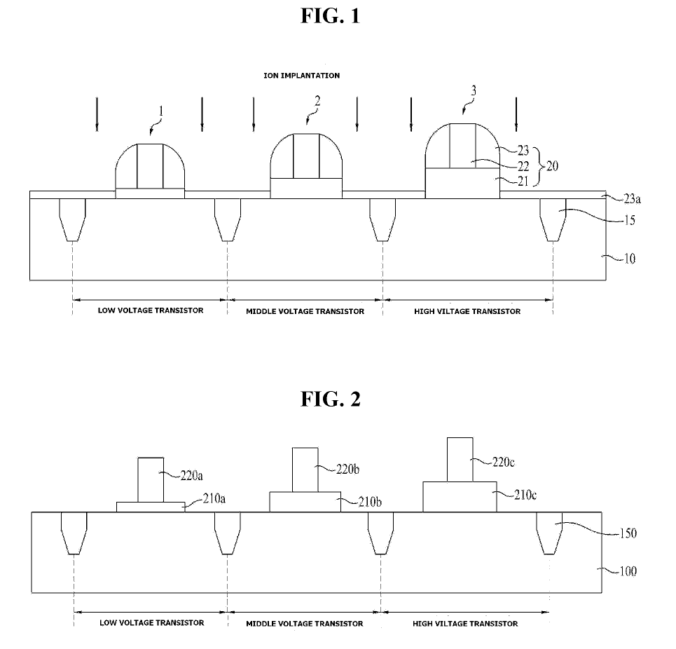

FIGS. 2 to 5 are cross-sectional views sequentially illustrating an exemplary LCD driver IC and an exemplary process of manufacturing an LCD driver IC in accordance with embodiments of the present invention.

### DETAILED DESCRIPTION OF THE INVENTION

Reference will now be made in detail to various embodiments of the present invention, examples of which are illustrated in the accompanying drawings.

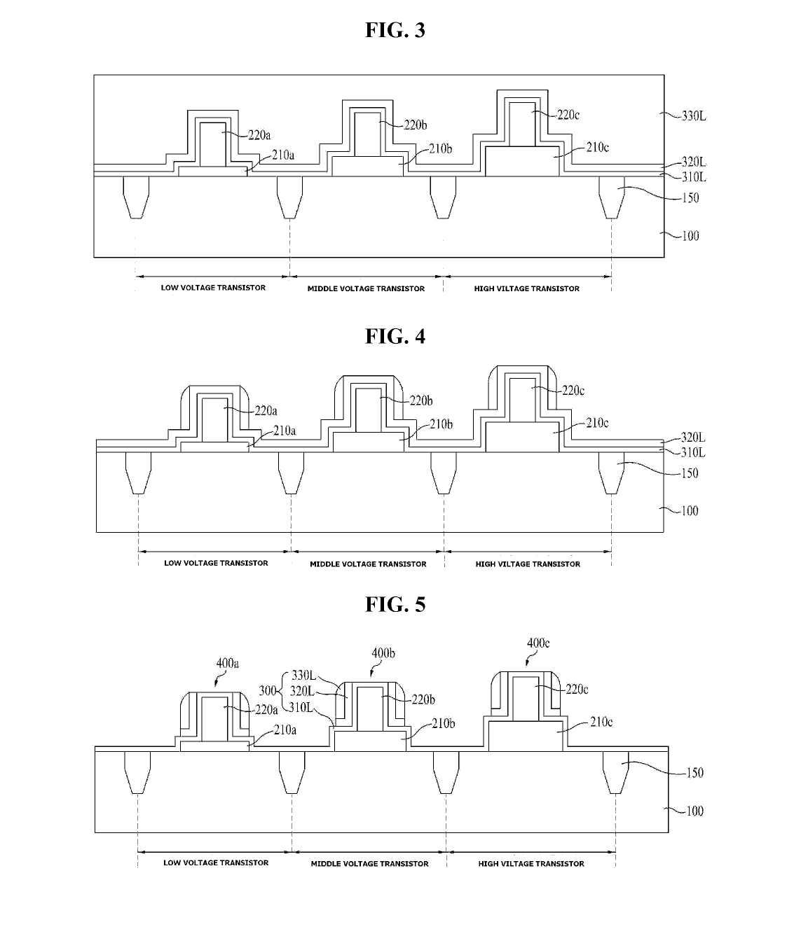

FIGS. 2 to 5 are cross-sectional views sequentially illustrating an exemplary process of manufacturing an LCD driver IC in accordance with embodiments of the present invention.

With reference to FIG. 2, an isolation layer 150, such as a local oxidation of silicon (LOCOS) isolation layer or a shallow trench isolation (STI) layer, is formed on a semiconductor substrate 100, thus defining a plurality of active regions (generally in areas other than the isolation layer 150). These active regions may be logic regions or pixel control regions of the driver IC. Transistors having different operating voltages, such as low-voltage transistors (LVT) operating at a voltage of 1.8˜5V, middle-voltage transistors (MVT) operating at a voltage of 5˜15V, and high-voltage transistors (HVT) operating at a voltage of 15˜40V, are formed on the respective active regions.

In order to form the transistors, gate insulating layers 210a, 210b, 210c are formed on the active regions. The gate insulating layers 210a, 210b, and 210c have different thicknesses according to the operating voltages of the transistors. For example, the gate insulating layer 210a for the low-voltage transistors generally has a thickness of 10˜50 Å (e.g., 10˜30 Å), the gate insulating layer 210b for the middle-voltage transistors has a thickness of 55˜300 Å (e.g., 100˜150 Å), and the gate insulating layer 210c for the high-voltage transistors has a thickness of 400˜1000 Å (e.g., 700˜800 Å).

Thereafter, gate electrodes 220a, 220b, and 220c are formed by depositing a conductive layer, such as a conductive polysilicon layer, on the gate insulating films 210a, 210b, and 210c and patterning the conductive layer. Forming the conductive layer may thus comprise depositing a silicon layer by chemical vapor deposition (CVD) of silicon from a silicon source such as silane gas (SiH₄), optionally implanting a heavy dose of a dopant (e.g., phosphorous [P] or boron [B]), annealing the deposited silicon (e.g., at a temperature of 600-1000° C.) to form polysilicon, and patterning the polysilicon by photolithography and etching. Thus, a plurality of gate patterns including the gate insulating films 210, 210b, and 210c and the gate electrodes 220a, 220b, and 220c may be formed on the active regions.

With reference to FIG. 3, in order to form a multi-layer spacer covering the gate electrodes 220a, 220b, and 200c on the semiconductor substrate 100, a first spacer material layer 310L, a second spacer material layer 320L, and a third spacer material layer 330L are sequentially deposited. The first spacer material layer 310L and the second spacer material layer 320L may comprise or be made of materials having a high etching selectivity ratio in a process for wet etching the second spacer material layer 320L, which will be described later. Similarly, the second spacer material layer 320L and the third spacer material layer 330L may comprise or be made of materials having a high etching selectivity ratio in a process for plasma dry etching the third spacer material layer 330L, which will be described later.

For example, the first spacer material layer 310L may comprise or consist essentially of a silicon oxide layer, and be formed by chemical vapor deposition or plasma enhanced chemical vapor deposition using an organic silicon oxide precursor, such as tetraethyl orthosilicate (TEOS).

Further, the second spacer material layer 320L comprises or consists essentially of a silicon nitride layer, and may be formed by chemical vapor deposition or plasma enhanced chemical vapor deposition using a silicon precursor such as silane and a nitrogen source (such as nitrogen gas [N₂] and/or ammonia [NH₃]) or a gas mixture containing nitrogen (N₂) and oxygen (O₂).

Further, the third spacer material layer 330L comprises or consists essentially of a silicon oxide layer, and may be the same material as that of the first spacer material layer 310L. The third spacer material layer 330L may be formed by chemical vapor deposition or plasma enhanced chemical vapor deposition using an organic silicon precursor, such as TEOS, in the same manner as the first spacer material layer 310L, or an inorganic silicon precursor, such as silane (SiH₄), and an oxygen source (such as O₂ or O₃).

The thickness of the first spacer material layer 310L is generally in the range of 50˜300 Å, and the thickness of the second spacer material layer 320L is generally in the range of 100˜300 Å. The thickness of the third spacer material layer 330L is not critical, as any excess thickness will generally be removed during the anisotropic etching (e.g., etch back) process to form the spacer. However, the thickness of the third spacer material layer 330L may be in the range of 50˜300 Å. In one embodiment, the third spacer material layer 330L has a thickness about equal to the thickness of the first spacer material layer 310L plus a thickness that is removed during any designated overetch process performed on the first spacer material layer 310L.

With reference to FIG. 4, the third spacer material layer 330L is removed by a plasma dry etching process (e.g., an anisotropic etch, or etchback). The above plasma dry etching process may use a mixed gas including a fluorine-containing gas, such as CHF₃, CF₄, or CH₂F₂, and an inert gas, such as Ar, which may have a high etching selectivity ratio for etching the third spacer material layer 330L relative to the second spacer material layer 320L, such that the second spacer material layer 320L serves as an etch stop layer. Through the first plasma dry etching process, the first, second, and third spacer material layers 310L, 320L, and 330L remain on the side walls of the gate electrodes 220a, 220b, and 220c, and the first and second spacer material layers 310L and 320L remain on the semiconductor substrate 100.

With reference to FIG. 5, the second spacer material layer 320L is removed by a wet etching process. The wet etching process may be performed using an aqueous solution of phosphoric acid (H₃PO₄), which has a high etching selectivity ratio for etching the second spacer material layer 330L relative to the first spacer material layer 310L. In one example, the etching selectivity ratio of the wet etching process is not less than approximately 1:20, and may be performed for 5˜10 minutes.

During the etching process of the second spacer material layer 320L, particles may be generated. Thus, after etching the second spacer material layer 320L, the semiconductor substrate 100 may be cleaned using a mixed aqueous solution of TMH, H₂O₂, and H₂O. The solution for cleaning the semiconductor substrate 100 may comprise from 1 to 5 parts of hydrogen peroxide (H₂O₂) and from 10 to 100 parts of water (H₂O) by weight or volume for each part of tetramethylammonium hydroxide (TMH). For example, the cleaning solution may have a composition ratio of TMH:H₂O₂:H₂O=1:2.3:36.7, and such cleaning may be performed for 10˜30 minutes.

A multi-layer spacer 300 including the first, second, and third spacer material layers 310L, 320L, and 330L is formed on the side walls of the gate electrodes 220a, 220b, and 220c and thus gates are completed, and only the first spacer material layer 310L remains on the semiconductor substrate 100.

Thereafter, in order to form source/drain terminals of the transistors 400a, 400b, and 400c, an ion implantation process using the gates as a mask is performed. In order to control the depth of the impurity ions implanted into the semiconductor substrate 100 by the ion implantation process, the first spacer material layer 310L is removed or is controllably etched to have a designated thickness, prior to the ion implantation process.

The above thickness control of the first spacer material layer 310L is performed only on the lowermost spacer material layer formed on the semiconductor substrate, on which transistors are formed having various operating voltages, for example, the low-voltage transistors 400a, the middle-voltage transistors 400b, and the high-voltage transistors 400c. For example, the thickness control of the first spacer material layer 310L may be performed only on the high-voltage transistors 400c. In this case, only the first spacer material layer 310L in the active regions of the high-voltage transistors 400c is etched, using an etching mask pattern such as a photoresist on the semiconductor substrate 100 in the regions of the low-voltage and middle-voltage transistors 400a and 400b.

However, the present invention is not limited to formation of the etching mask to control the thickness of the first spacer material layer 310L. For example, the etching mask pattern may be omitted and the thickness of the first spacer material layer 310L may be controlled throughout the entire surface of the semiconductor substrate 100 using plasma dry etching, as the occasion demands.

In the method of manufacturing the LCD driver IC in accordance with embodiments of the present invention, first, second, and third spacer material layers are stacked on gate electrodes, and plasma dry etching and wet etching are performed thereon to selectively remove the first, second, and (optionally) part or all of third spacer material layers, thus controlling the thickness of the first spacer material layer on active regions in which source/drain regions will be formed. Thereby, the depth of impurity ions implanted by an ion implantation process is controlled and variations in such implantation depths are reduced, and thus the driver IC has a high reliability.

It will be apparent to those skilled in the art that various modifications and variations can be made in the present invention without departing from the spirit or scope of the inventions. Thus, it is intended that the present invention covers the modifications and variations of this invention within the scope of the appended claims and their equivalents.

What is claimed is:

1. A method of manufacturing an LCD driver IC comprising:
forming a plurality of gate patterns on a semiconductor substrate by sequentially forming a plurality of gate insulating films and gate electrodes thereon;
sequentially depositing a plurality of spacer material layers covering the gate electrodes;
forming spacers respectively on side walls of the gate electrodes by performing an etchback process on the plurality of spacer material layers such that a lowermost spacer material layer remains on the semiconductor substrate; and
etching the lowermost spacer material layer to remove or control a thickness of the lowermost spacer material layer.

2. The method according to claim 1, wherein sequentially depositing the plurality of spacer material layers comprises sequentially depositing a first spacer material layer, a second spacer material layer different from the first spacer material layer, and a third spacer material layer different from the second spacer material layer.

3. The method according to claim 2, wherein forming the spacers on the side walls of the gate electrodes includes:
performing the etchback process on the first spacer material layer; and
removing the exposed second spacer material layer by wet etching.

4. The method according to claim 3, wherein the etchback process on the first spacer material layer comprises plasma dry etching.

5. The method according to claim 3, comprising etching the lowermost spacer material layer to control the thickness of the lowermost spacer material layer.

6. The method according to claim 5, wherein the thickness of the first spacer material layer is controlled by dry etching.

7. The method according to claim 2, wherein the first, second, and third spacer material layers respectively comprise a first silicon oxide, a silicon nitride, and a second silicon oxide.

8. The method according to claim 7, wherein the first spacer material layer and the third spacer material layer comprise a TEOS-based silicon oxide.

9. The method according to claim 5, wherein the wet etching comprises etching with an aqueous solution of at least one acid selected from the group consisting of hydrofluoric acid (HF), nitric acid (HNO₃), acetic acid (CH₃COOH), and phosphoric acid (H₃PO₄).

10. The method according to claim 3, further comprising cleaning the semiconductor substrate after removing the exposed second spacer material layer.

11. The method according to claim 10, wherein the semiconductor substrate is cleaned using a cleaning solution having a composition ratio of tetramethylammonium hydroxide (TMH):H₂O₂:H₂O=1:2.3:36.7 for 10˜30 minutes.

12. The method according to claim 2, wherein the first spacer material layer has a thickness in the range of 50˜300 Å, and the second spacer material layer has a thickness in the range of 100˜300 Å.

13. The method according to claim 1, wherein:
the plurality of gate patterns includes a low-voltage transistor gate pattern operating at a voltage of 1.8˜5V, a middle-voltage transistor gate pattern operating at a voltage of 5˜15V, and a high-voltage transistor gate pattern operating at a voltage of 15˜40V; and

14. The method according to claim 1, wherein:
the plurality of gate patterns includes a low-voltage gate insulating layer having a first thickness, a second gate insulating layer having a second thickness larger than the first thickness, and a third gate insulating layer having a third thickness smaller than the second thickness.

15. The method according to claim 14, wherein the first thickness is 10˜30 Å, the second thickness is 100˜150 Å, and the third thickness is 700˜800 Å.

16. An LCD driver IC comprising:
a first gate insulating film in a low voltage region of the LCD driver IC;
a second gate insulating film in a middle voltage region of the LCD driver IC;
a third gate insulating film in a high voltage region of the LCD driver IC;
first, second and third gate electrodes respectively on the first, second and third gate insulating films;
a multi-layer spacer on side walls of the first, second and third gate electrodes, comprising a lowermost spacer layer, a second spacer layer, and an uppermost spacer layer, the second spacer layer consisting essentially of a material having high etch selectivity to the lowermost and uppermost spacer layers.

17. The LCD driver according to claim 16, wherein the lowermost, second, and uppermost spacer material layers respectively comprise a first silicon oxide, silicon nitride, and a second silicon oxide.

18. The LCD driver according to claim 17, wherein the lowermost spacer material layer has a thickness in the range of 50˜300 Å, and the second spacer material layer has a thickness in the range of 100˜300 Å.

19. The LCD driver according to claim 16, wherein the first, second and third gate electrodes and the first, second and third gate insulating films respectively form a low-voltage transistor gate pattern operating at a voltage of 1.8˜5V, a middle-voltage transistor gate pattern operating at a voltage of 5˜15V, and a high-voltage transistor gate pattern operating at a voltage of 15˜40V.

20. The LCD driver according to claim 16, wherein the first gate insulating layer has a first thickness of 10˜30 Å, the second gate insulating layer has a second thickness of 100˜150 Å, and the third gate insulating layer has a third thickness of 700˜800 Å.
